(19) United States
(12) Patent Application Publication
(10) Pub. No.: US 2025/0266315 A1
(43) Pub. Date: Aug. 21, 2025

(54) SEMICONDUCTOR MODULE

(71) Applicant: FUJI ELECTRIC CO., LTD., Kawasaki-shi (JP)

(72) Inventor: Masanori TANAKA, Kawasaki-shi (JP)

(73) Assignee: FUJI ELECTRIC CO., LTD., Kawasaki-shi (JP)

(21) Appl. No.: 19/006,550

(22) Filed: Dec. 31, 2024

(30) Foreign Application Priority Data
Feb. 15, 2024 (JP) 2024-020758

(51) Int. Cl. H01L 23/367; H01L 23/31; H01L 23/495

(52) U.S. Cl. CPC H01L 23/367; H01L 23/3107; H01L 23/49568

(57) ABSTRACT

A semiconductor module includes a sealing member sealing a semiconductor element, and first and second heat dissipation members exposed to an outside respectively from first and second sealing surfaces of the sealing member. The second heat dissipation member has a recess at an outer periphery of an exposed surface recessed downward. The second heat dissipation member is located overlapping the first heat dissipation member such that a line on the exposed surface of the first heat dissipation member, which is parallel to one of the four sides of the first heat dissipation member that is closest among the four sides to the recess and passes through a point at an outer edge of the recess that is farthest from the one side, passes within the exposed surface of the second heat dissipation member in the plan view.

### CROSS-REFERENCE TO RELATED APPLICATION

This application is based upon and claims the benefit of priority to Japanese Patent Application No. 2024-020758, filed on Feb. 15, 2024, the entire contents of which are incorporated herein by reference.

### BACKGROUND OF THE INVENTION

### 1. Technical Field

The present invention relates to a semiconductor module.

### 2. Description of the Related Art

A dual inline package (DIP) type semiconductor module includes a semiconductor module in which a heat dissipation member is exposed on a surface of a sealing member that seals a semiconductor element. In the sealing step when this type of semiconductor module is manufactured, the heat dissipation member is pressed against the mold with a pin to prevent the sealing member from flowing between the heat dissipation member and the mold (see, for example, JP 2022-67815 A).

### SUMMARY OF THE INVENTION

As the semiconductor module described above, there is a double-sided heat dissipation type semiconductor module in which a heat dissipation member is exposed to both a first surface and a second surface of a sealing member, which are in a front and back relationship. However, when the heat dissipation member is pressed against the mold with the pin in the sealing step in manufacturing the double-sided heat dissipation type semiconductor module, there are large restrictions on the dimension, arrangement, and the like of the heat dissipation member exposed on the first surface and the heat dissipation member exposed on the second surface.

In one aspect, an object of the present invention is to alleviate restriction on a heat dissipation member in a double-sided heat dissipation type semiconductor module.

A semiconductor module according to one aspect includes: a sealing member that seals a semiconductor element; a first heat dissipation member exposed from a first surface of the sealing member; and a second heat dissipation member exposed from a second surface opposite to the first surface of the sealing member, in which a recess that is located at an end portion of the first heat dissipation member in a plan view of the second surface and overlaps with the first heat dissipation member and is retracted closer to the first surface than the second surface is formed on the second surface of the sealing member, and a planar shape of the second heat dissipation member in a plan view of the second surface is a shape in which a line parallel to a side of the first heat dissipation member passing through a point farthest from the side of the first heat dissipation member close to the recess in the recesses passes through the second heat dissipation member.

According to the above aspect, it is possible to alleviate the restriction of the heat dissipation member in the double-sided heat dissipation type semiconductor module.

### BRIEF DESCRIPTION OF THE DRAWINGS

FIG. 1 is a plan view of a semiconductor module according to a first embodiment;

FIG. 2 is a cross-sectional view illustrating a configuration example in a sealing member in the semiconductor module illustrated in FIG. 1;

FIG. 3 is a circuit diagram illustrating a circuit configuration example of the semiconductor module illustrated in FIG. 1;

FIG. 4 is a flowchart illustrating and example of the method for manufacturing the semiconductor module according to the first embodiment;

FIG. 5 is a cross-sectional view illustrating a state of a mold at the start of a sealing step;

FIG. 6 is a cross-sectional view illustrating a state of a mold during an injection step and a temporary curing step;

FIG. 7 is a cross-sectional view illustrating a state of a mold after a pin extraction step;

FIG. 8 is a partial cross-sectional view illustrating an example of a tip shape of a pin and a shape of a through hole of a second heat dissipation member;

FIG. 9 is a partial cross-sectional view illustrating an example of a recess formed in a through hole of the second heat dissipation member in a main curing step;

FIGS. 10A and 10B are plan views illustrating a modification of the planar shape of the second heat dissipation member;

FIG. 11 is a plan view illustrating a modification of the arrangement of pins to be pressed against the first heat dissipation member;

FIG. 12 is a view illustrating a feature of a planar shape of the second heat dissipation member that can be adopted in the semiconductor module according to the first embodiment;

FIG. 13 is a partial cross-sectional view illustrating a modification of the method of pressing the heat dissipation member against the mold;

FIG. 14 is a plan view of a semiconductor module according to the second embodiment;

FIG. 15 is a cross-sectional view illustrating a configuration example in a sealing member in the semiconductor module illustrated in FIG. 14; and

FIG. 16 is a cross-sectional view illustrating a configuration example of a mold used for manufacturing the semiconductor module according to a second embodiment.

### DETAILED DESCRIPTION

Hereinafter, an embodiment of the present invention will be described in detail with reference to the drawings. A “semiconductor module” in the following description is obtained by sealing a semiconductor element (a semiconductor chip) with an insulating material, and may be referred to as a “semiconductor device”, a “semiconductor package”, or the like.

An X axis, a Y axis, and a Z axis in each of the drawings to be referred to are illustrated for the purpose of defining a plane and a direction in the illustrated semiconductor module. The X axis, the Y axis, and the Z axis are perpendicular to each other and form a right-handed system. In the following description, a direction parallel to the X axis is referred to as an X direction, a direction parallel to the Y axis is referred to as a Y direction, and a direction parallel to the Z axis is referred to as a Z direction. In addition, in a case where each of the X direction, the Y direction, and the Z direction is associated with a direction of an arrow (positive or negative) of the X axis, the Y axis, and the Z axis illustrated, a “positive side” or a “negative side” is added.

In the present specification, the Z direction may be referred to as a vertical direction. In the present specification, “on” and “upper side” are intended to be on the positive side in the Z direction with respect to the reference surface, member, position, and the like, and “below” and “lower side” are intended to be on the negative side in the Z direction with respect to the reference surface, member, position, and the like. For example, when it is described that “the member B is disposed on the member A”, the member B is disposed on the positive side in the Z direction as viewed from the member A. Further, when the term “upper surface of the member A” is described, the surface includes a surface that is positioned at the end of the member A on the positive side in the Z direction and faces the positive side in the Z direction. These directions and surfaces associated with the directions are words used for convenience of description, and a correspondence relationship with the directions of the X axis, the Y axis, and the Z axis may change depending on a mounting posture of the semiconductor module and the like. For example, in the present specification, a surface located at an end portion on the positive side in the Z direction of the semiconductor element, the heat dissipation member, or the like is referred to as an upper surface, and a surface opposite to the upper surface is referred to as a lower surface. However, the present invention is not limited thereto, and a surface located at an end portion on the negative side in the Z direction may be referred to as an upper surface, and a surface opposite thereto may be referred to as a lower surface.

An aspect ratio and a size relationship between respective members in each drawing are merely schematically represented, and do not necessarily coincide with a relationship in a semiconductor module actually manufactured. For convenience of description, it is also assumed that the size relationship between the respective members is exaggerated. In addition, some of the cross-sectional views illustrate a cross-sectional configuration of the semiconductor module cut along a virtual cutting line that cannot be accurately illustrated in the plan view for convenience of description.

The descriptions such as “not illustrated” and the like in the present specification mean that the components to which the descriptions are attached are not clearly shown in the drawings. For example, “a first main electrode not illustrated” intends either that a portion (for example, a figure, a line, or the like) representing the first main electrode is not illustrated in the drawing, or that neither a leader line nor a sign clearly indicating a portion corresponding to the first main electrode in the drawing exists, depending on the context. In addition, the underlined reference signs in the drawings indicate the entire components including a plurality of portions distinguished from one another by a plurality of reference signs.

A semiconductor module to be exemplified in the following description may be applied to, for example, a power conversion device such as an industrial or electrical (for example, an in-vehicle motor's) inverter device. Thus, in the following description, detailed description of the same or similar configuration, function, operation, manufacturing method, and the like as or to those of a known semiconductor module will be omitted.

### First Embodiment

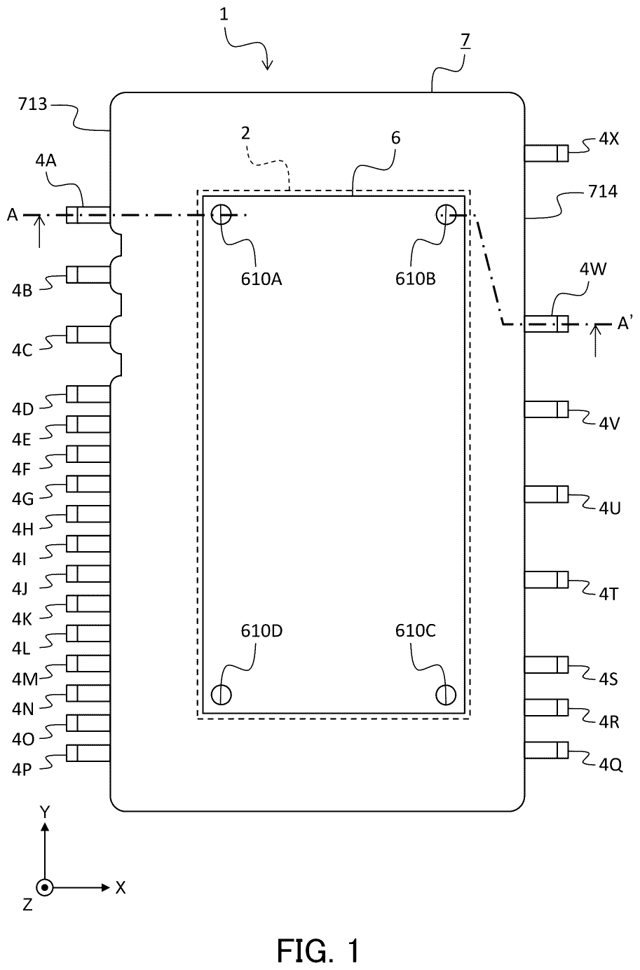

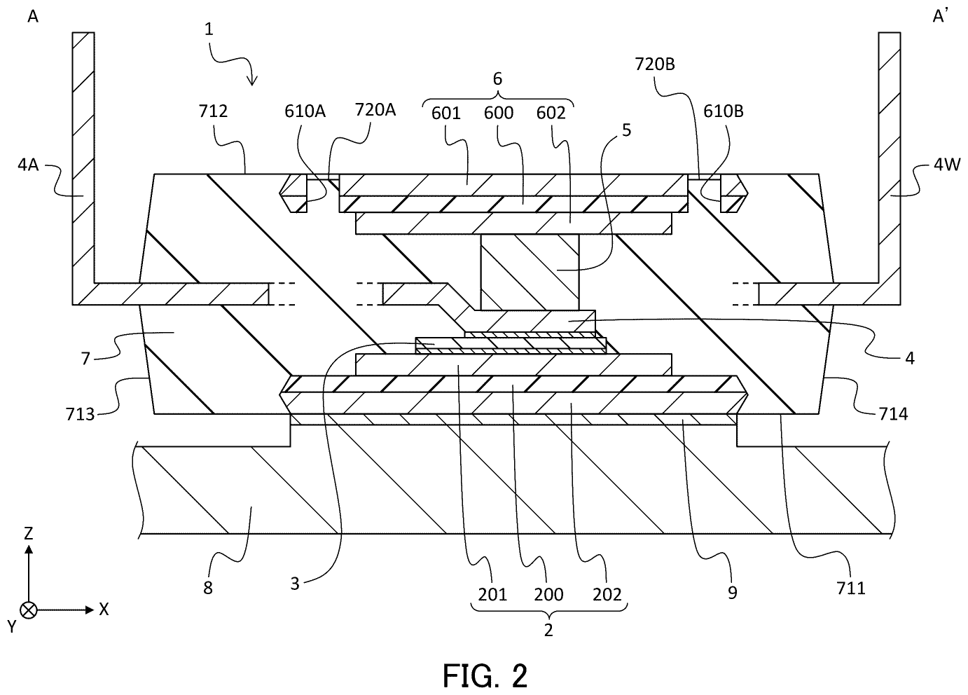

FIG. 1 is a plan view of a semiconductor module according to a first embodiment. FIG. 2 is a cross-sectional view illustrating a configuration example in a sealing member in the semiconductor module illustrated in FIG. 1. The cross-sectional view of FIG. 2 illustrates a cross-sectional configuration example of a semiconductor module 1 cut by a virtual line A-A′ obtained by connecting an alternate long and short dash line passing through one lead 4A located on the negative side in the X direction to another alternate long and short dash line passing through another lead 4W located on the positive side in the X direction in the semiconductor module 1 illustrated in FIG. 1. In FIG. 1, a broken line representing the outer shape of a first heat dissipation member 2 and a solid line representing the outer shape of a second heat dissipation member 6 may partially or entirely overlap each other. A part or all of the solid line representing the outer shape of the second heat dissipation member 6 may pass through the outside of a region surrounded by a broken line representing the outer shape of the first heat dissipation member 2.

The semiconductor module 1 illustrated in FIGS. 1 and 2 includes the first heat dissipation member 2, a semiconductor element 3, leads 4 (4A to 4X), a spacer 5, the second heat dissipation member 6, and a sealing member 7. Although the semiconductor module 1 may include a cooler 8 (see FIG. 2) positioned below the first heat dissipation member 2, a dual inline package (DIP) semiconductor package excluding the cooler 8 illustrated in FIG. 2 is referred to as the semiconductor module 1 in the present specification. In addition, in the present specification, when a specific lead among the plurality of leads 4A to 4X is designated, a reference sign (any one of 4A to 4X) allocated to the specific lead is described in FIG. 1, and in other cases, the lead is simply described as the “lead 4”. In addition, in the present specification, for other components to which reference numerals assigned with alphabets such as “A” to “D” are assigned, reference numerals assigned with alphabets will be described when referring to specific components, and reference numerals without alphabets will be described in other cases.

The first heat dissipation member 2 and the second heat dissipation member 6 are members for dissipating heat generated by the semiconductor element 3 sealed by the sealing member 7 during operation to the outside of the semiconductor module 1. The first heat dissipation member 2 includes an insulating substrate 200, a first conductor pattern 201 provided on the upper surface of the insulating substrate 200, and a second conductor pattern 202 provided on the lower surface of the insulating substrate 200, and the lower surface of the second conductor pattern 202 is exposed from a lower surface (first surface) 711 of the sealing member 7. A lower surface of the second conductor pattern 202 of the first heat dissipation member 2 is flush with the lower surface 711 of the sealing member 7. The second heat dissipation member 6 includes an insulating substrate 600, a first conductor pattern 601 provided on the upper surface of the insulating substrate 600, and a second conductor pattern 602 provided on the lower surface of the insulating substrate 600, and the upper surface of the first conductor pattern 601 is exposed from an upper surface (second surface) 712 of the scaling member 7. An upper surface of the first conductor pattern 601 of the second heat dissipation member 6 is flush with the upper surface 712 of the sealing member 7. In the following description, “the lower surface of the first heat dissipation member 2” refers to the lower surface of the second conductor pattern 202 of the first heat dissipation member 2, and “the upper surface of the second heat dissipation member 6” refers to the upper surface of the first conductor pattern 601 of the second heat dissipation member 6.

The insulating substrate 200 of the first heat dissipation member 2 may be, for example, a sheet-like insulating resin such as an epoxy resin (resin insulating sheet). The resin insulating sheet is formed by adding insulating particles of a nitride such as boron nitride (BN) or aluminum nitride (AlN) or an oxide such as alumina (Al₂O₃) having high thermal conductivity to an epoxy resin or the like to form a sheet, and is formed on the second conductor pattern 202. The first conductor pattern 201 and the second conductor pattern 202 of the first heat

dissipation member 2 are formed of, for example, a metal foil such as copper or aluminum. As the metal foil, a metal foil having a thickness of 0.1 mm to 3.0 mm is used. In addition, the second conductor pattern 202 may be the cooler 8 or a part thereof. The conductor pattern may be referred to as a conductive pattern, a conductor layer, a conductive layer, or the like.

A plurality of conductor patterns including the first conductor pattern 201 may be formed on the upper surface of the insulating substrate 200. When the insulating substrate 200 is a resin insulating sheet, a plurality of regions where the first conductor patterns 201 do not overlap are provided in a portion along an end side of the insulating substrate 200 in a plan view of the upper surface of the insulating substrate 200 on the upper surface of the insulating substrate 200. That is, the first conductor pattern 201 may have a smaller area and a shorter width than the insulating substrate 200, and the upper surface (front surface) of the insulating substrate 200 may be exposed to the sealing member 7. Furthermore, the insulating substrate 200 may be a ceramic substrate having high thermal conductivity, such as aluminum oxide (Al₂O₃) or aluminum nitride (AlN). As these insulating substrates 200, those having a thickness of 0.1 mm to 0.4 mm are used. In this case, the second conductor pattern 202 may have a smaller area and a shorter width than the insulating substrate 200, and the lower surface (back surface) of the insulating substrate 200 may be exposed to the sealing member 7. As will be described later, the insulating substrate 200 in the case of providing a through hole in the first heat dissipation member 2 is preferably a resin insulating sheet from the viewpoint of workability.

The second heat dissipation member 6 needs to dissipate heat generated from the semiconductor element 3 upward and to achieve electrical insulation from the lead 4. In the present specification, a stacked body of “conductor layer/insulating substrate/conductor layer” is exemplified, but the second heat dissipation member 6 may be a stacked body of “conductor layer/insulating substrate”. Each of the insulating substrate 600, the first conductor pattern 601, and the second conductor pattern 602 of the second heat dissipation member 6 may be formed of, for example, the same material as the insulating substrate 200, the first conductor pattern 201, and the second conductor pattern 202 of the first heat dissipation member 2. On the lower surface of the insulating substrate 600, for example, a plurality of conductor patterns including the second conductor pattern 602 corresponding to the shapes of the plurality of conductor patterns including the first conductor pattern 201 provided on the insulating substrate 200 of the first heat dissipation member 2 may be formed. When the insulating substrate 600 is a resin insulating sheet, a plurality of regions where the second conductor patterns 602 do not overlap are provided in a portion along an end side of the insulating substrate 600 in a plan view of the lower surface of the insulating substrate 600 on the lower surface of the insulating substrate 600. Through holes 610 (610A to 610D) penetrating from the lower surface of the insulating substrate 600 to the upper surface of the first conductor pattern 601 are formed in some of the plurality of regions of the second heat dissipation member 6 not overlapped with the second conductor pattern 602. In a plan view of the upper surface 712 of the sealing member 7, the through hole 610 of the second heat dissipation member 6 is formed so as to overlap with a region that is a corner of the insulating substrate 200 of the first heat dissipation member 2 and in which the first conductor pattern 201 is not disposed. In addition, the second conductor pattern 602 may have substantially the same size as the insulating substrate 600, and in this case, the through hole 610 may be provided in a stacked body portion in which the first conductor pattern 601, the insulating substrate 600, and the second conductor pattern 602 are stacked. A part of the scaling member 7 flows into the through hole 610 of the second heat dissipation member 6 so as to form a recess 720 (720A and 720B in FIG. 2) retracted from the upper surface of the first conductor pattern 601 in the same plane as the upper surface 712 of the scaling member 7 toward the lower surface side.

The semiconductor element 3, the lead 4, and the spacer 5 are disposed between first heat dissipation member 2 and second heat dissipation member 6. A plurality of semiconductor elements 3 may be disposed. The plurality of semiconductor elements 3 may have the same function or may include a plurality of types of semiconductor elements having different functions. The semiconductor element 3 may be referred to as a semiconductor chip, a die, or the like.

The semiconductor element 3 may be, for example, a reverse conducting (RC)-IGBT element obtained by integrating an insulated gate bipolar transistor (IGBT) element, which is a switching element, with a function of a diode element such as a free wheeling diode (FWD) clement connected in antiparallel to the IGBT element. In this type of semiconductor element 3, a first main electrode (not illustrated) is provided on the lower surface, and a second main electrode and a control electrode (gate electrode) (not illustrated) are provided on the upper surface. When the switching element of the semiconductor element 3 is an IGBT clement, the first main electrode on the lower surface side may be referred to as a collector electrode, and the second main electrode on the upper surface side may be referred to as an emitter electrode. A semiconductor substrate forming the switching element and the diode element in the semiconductor element 3 is not limited to a silicon substrate, and may be, for example, a substrate using a wide band gap semiconductor such as a silicon carbide (SiC) substrate or a gallium nitride (GaN) substrate.

In the semiconductor element 3, a first main electrode on the lower surface is bonded to first conductor pattern 201 of the first heat dissipation member 2 by a first bonding material (not illustrated), and a second main electrode on the upper surface is bonded to the lead 4 by a second bonding material (not illustrated). The control electrode on the upper surface of the semiconductor element 3 is connected to a lead (not illustrated) different from the lead 4 bonded to the second main electrode directly or via another semiconductor element (not illustrated). The spacer 5 is a heat conducting member that connects the lead 4 bonded to the second main electrode of the semiconductor element 3 and the second conductor pattern 602 of the second heat dissipation member 6. The spacer 5 may be, for example, a rectangular metal member such as a copper block. The second conductor pattern may be integrated with the second conductor pattern of the second heat dissipation member. The electrode on the upper surface of the semiconductor element 3 may be connected to the lead 4 by a bonding wire. The spacer 5 may be disposed on the upper surface of the conductor pattern bonded to an electrode of the semiconductor element 3 such as the first conductor pattern 201 of the first heat dissipation member 2.

The lead 4 includes a portion (inner lead) embedded in the sealing member 7 together with the semiconductor element 3 and the spacer 5, and a portion (outer lead) extending outward from the scaling member 7. The outer lead of the lead 4 extends outward from a pair of end surfaces 713 and 714 of the end surfaces (side surfaces) of the sealing member 7 in a direction parallel to the in-plane direction of the upper surface of the semiconductor element 3. The outer lead of the lead 4 is bent at a predetermined bending position so that the extending direction changes to the direction toward the upper surface 712 of the sealing member 7. The inner lead is connected to the upper electrode (for example, the second main electrode) of the semiconductor element 3 via a bonding material such as solder.

The sealing member 7 is a resin composition containing a resin and an inorganic filler. As the resin, for example, an epoxy resin is often used, but a main agent such as a bisphenol A type, a cresol novolac type, a biphenyl type, or an alicyclic epoxy is used in combination with a curing agent such as an acid anhydride or a phenol resin. A plurality of these may be used in combination. Silica or alumina is used as the inorganic filler, but silica is mainly used from the viewpoint of accessibility and cost. A plurality of these may be used in combination. In addition, additives such as a phosphorus compound and a metal hydroxide may be used for improving flame retardancy and the like. Further, the resin of the sealing member 7 is a thermosetting resin, and is filled in a mold and molded by being heated and melted. As the melt viscosity, a melt viscosity of 4 Pa·s to 100 Pa·s is preferably used because defects such as voids can be reduced.

In the semiconductor module 1 of the present embodiment, the second conductor pattern 202 of the first heat dissipation member 2 exposed from the lower surface 711 of the sealing member 7 is connected to the cooler 8 via the heat conducting member 9 such as thermal grease or thermal compound. The cooler 8 is not limited to a specific configuration and cooling system. Some of the heat generated by the semiconductor element 3 during the operation of the semiconductor module 1 illustrated in FIG. 2 is conducted to the cooler 8 via the first heat dissipation member 2 and dissipated by heat exchange or the like in the cooler 8. Another part of the heat generated by the semiconductor element 3 is conducted through the lead 4 bonded to the second main electrode and dissipated from the outer lead of the lead 4. Still another part of heat generated by semiconductor element 3 is conducted to second heat dissipation member 6 via the lead 4 and the spacer 5, and is dissipated from the first conductor pattern 601 of the second heat dissipation member 6.

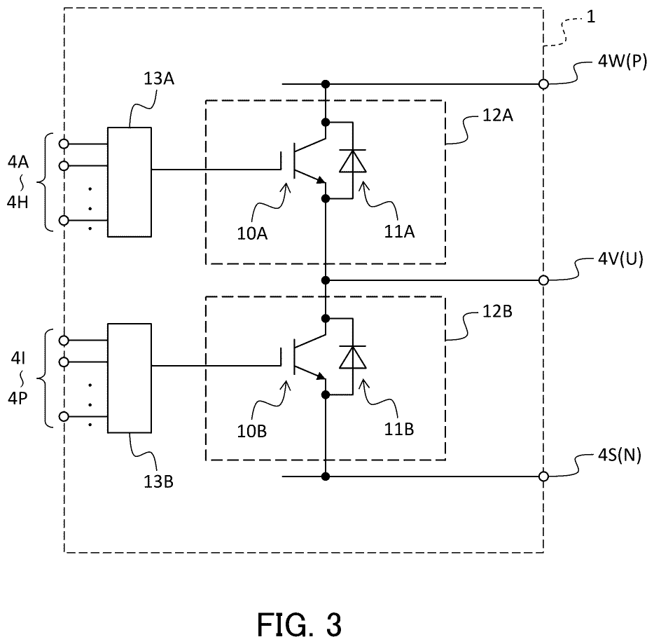

The semiconductor module 1 described above with reference to FIGS. 1 and 2 may be a module including a three-phase inverter circuit and a control circuit, which may be referred to as an intelligent power module (IPM). FIG. 3 is a circuit diagram illustrating a circuit configuration example of the semiconductor module illustrated in FIG. 1. FIG. 3 illustrates only a part of the three-phase inverter circuit and the control circuit included in the semiconductor module 1.

The semiconductor module 1 has a power conversion circuit formed therein and configured to convert a direct current into a three-phase alternating current of a U-phase, a V-phase, and a W-phase and to output the three-phase alternating current. FIG. 3 illustrates a half-bridge inverter circuit that outputs a direct current as a U-phase alternating current. The illustrated half-bridge inverter circuit includes two IGBT elements 10A and 10B connected in series between the first lead 4W and the second lead 4S, and diode elements (FWD elements) 11A and 11B respectively connected in antiparallel to the two IGBT elements 10A and 10B. The first lead 4W is a P terminal connected to the positive electrode of the DC power supply, and the second lead 4S is an N terminal connected to the negative electrode of the DC power supply. A collector electrode of the IGBT element 10A of an upper arm 12A of the two IGBT elements is connected to the first lead 4W, and an emitter electrode of the IGBT element 10B of a lower arm 12B is connected to the second lead 4S. An emitter electrode of the IGBT element 10A of the upper arm 12A and a collector electrode of the IGBT element 10B of the lower arm 12B are connected to a third lead 4V which is an output terminal of a U-phase alternating current. A gate of the IGBT element 10A of the upper arm 12A is connected to a first control circuit 13A, and a gate of the IGBT element 10B of the lower arm 12B is connected to a second control circuit 13B. The leads 4A to 4H each extending from the end surface 713 of the sealing member 7 to the negative side in the X direction are connected to the first control circuit 13A, and the leads 4I to 4P each extending from the end surface 713 to the negative side in the X direction are connected to the second control circuit 13B.

Each of the half-bridge inverter circuit that outputs the direct current as a V-phase alternating current and the half-bridge inverter circuit that outputs the direct current as a W-phase alternating current may have a circuit configuration similar to that of the half-bridge inverter circuit of the U-phase illustrated in FIG. 3. The first control circuit 13A controls a voltage to be applied to the gate of the IGBT element 10A of the U-phase, the V-phase, and the W-phase upper arms 12A based on drive power supply voltages and the like input from the plurality of leads 4A to 4H. The second control circuit 13B controls a voltage applied to the gate of the IGBT element 10B of the U-phase, the V-phase, and the W-phase lower arm 12B based on drive power supply voltage and the like input from the plurality of leads 4I to 4P.

The circuit configuration of the semiconductor module 1 described above with reference to FIG. 3 is merely an example of a power conversion circuit including the semiconductor element 3 sealed by the sealing member 7. The power conversion circuit may be configured such that the emitter of the IGBT element 10A of the upper arm 12A is connected to the first control circuit 13A, the emitter of the IGBT element 10A of the lower arm 12B is connected to the second control circuit 13B, and the control circuit controls the voltage applied to the gate with the emitter potential as the ground. Wiring that connects the emitter and the control circuit in this type of power conversion circuit is referred to as auxiliary emitter wiring, sense emitter wiring, or the like. The power conversion circuit including the semiconductor element 3 may be a power conversion circuit having another circuit configuration. The semiconductor module 1 may include a circuit different from the power conversion circuit, a part of the power conversion circuit may be formed, or only a circuit different from the power conversion circuit may be formed.

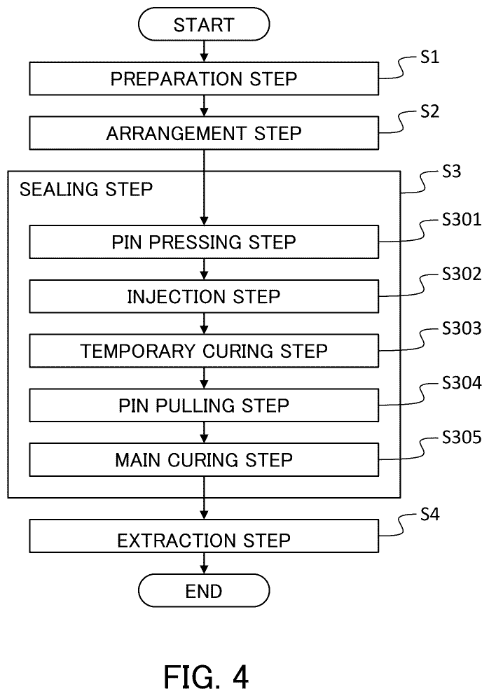

FIG. 4 is a flowchart for explaining the method for manufacturing the semiconductor module according to the first embodiment. The manufacturing step of the semiconductor module 1 of the present embodiment includes, for example, a preparation step S1, an arrangement step S2, a sealing step S3, and an extraction step S4 illustrated in FIG. 4. The sealing step S3 includes a pin pressing step S301, an injection step S302, a temporary curing step S303, a pin pulling step S304, and a main curing step S305.

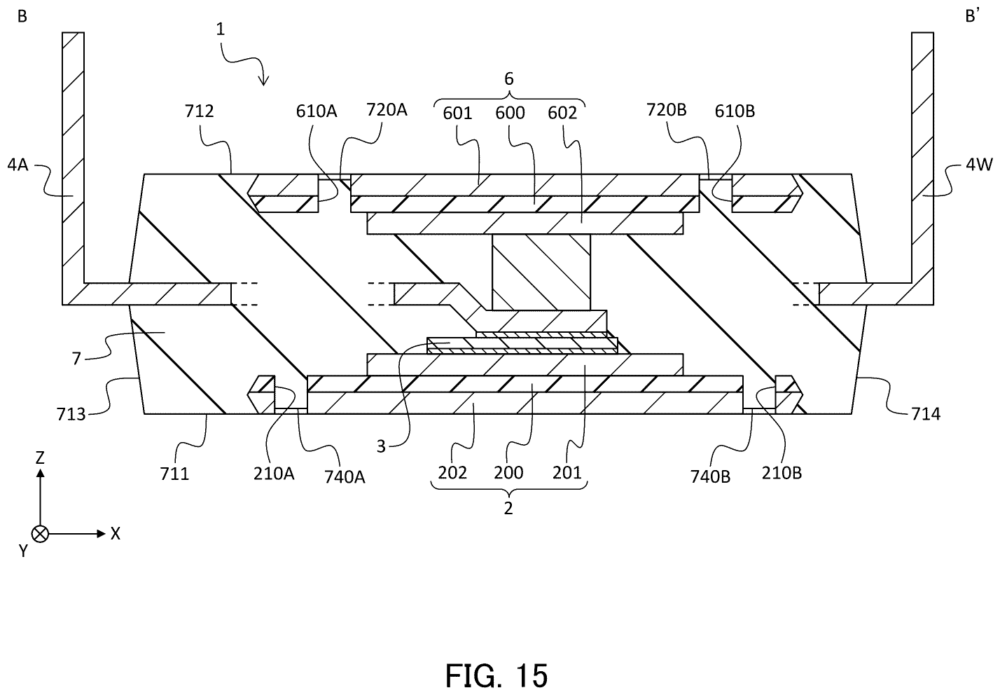

The preparation step S1 is a step of preparing a member to be sealed by the sealing member 7. In the preparation step S1, the lead frame in which the semiconductor element 3 and the lead 4 are integrally held, the spacer 5, and the second heat dissipation member 6 are disposed on the upper surface of the first heat dissipation member 2, and fixed. The first heat dissipation member 2 and the second heat dissipation member 6 are manufactured, for example, according to a known method for manufacturing a double-sided printed wiring board using the above-described resin insulating sheet as an insulating substrate. The through hole 610 described above with reference to FIGS. 1 and 2 is formed in the second heat dissipation member 6. The through hole 610 of the second heat dissipation member 6 and a through hole 210 (see FIG. 15) of the first heat dissipation member 2 to be described later can be formed, for example, at predetermined positions of a stacked body of the first conductor pattern, the insulating substrate, and the second conductor pattern by machining such as pressing or laser machining. In the preparation step S1, for example, the semiconductor element 3, the lead frame (lead 4), the spacer 5, and the second heat dissipation member 6 are stacked on the upper surface of the first conductor pattern 201 of the first heat dissipation member 2 via a bonding material such as cream solder or plate solder, and then the bonding material is melted and cured by a reflow device to be integrated.

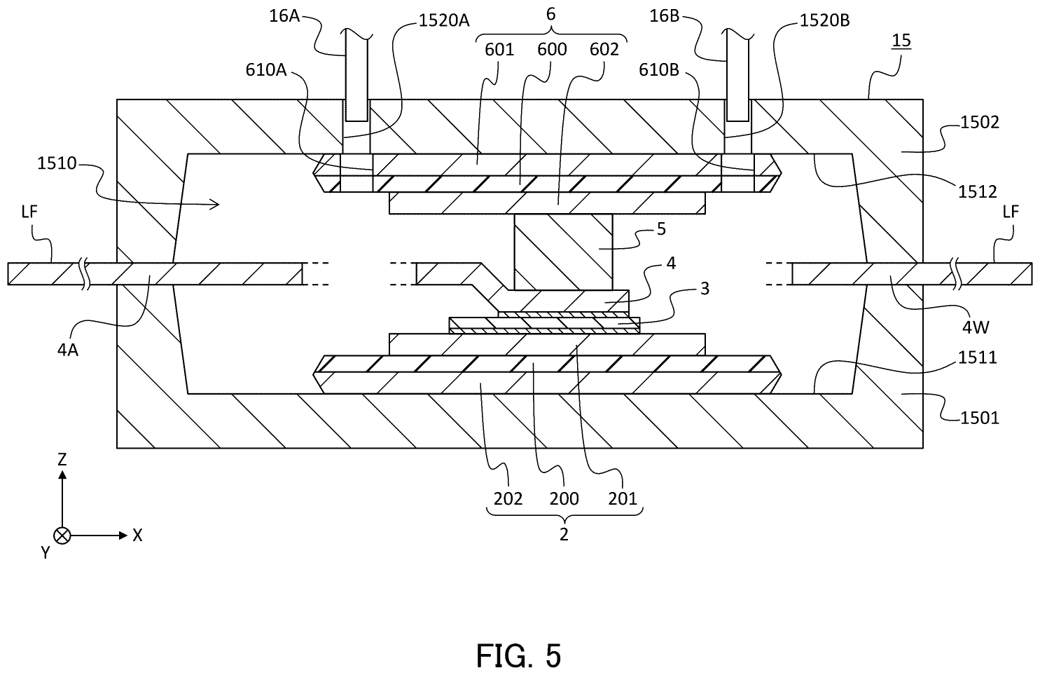

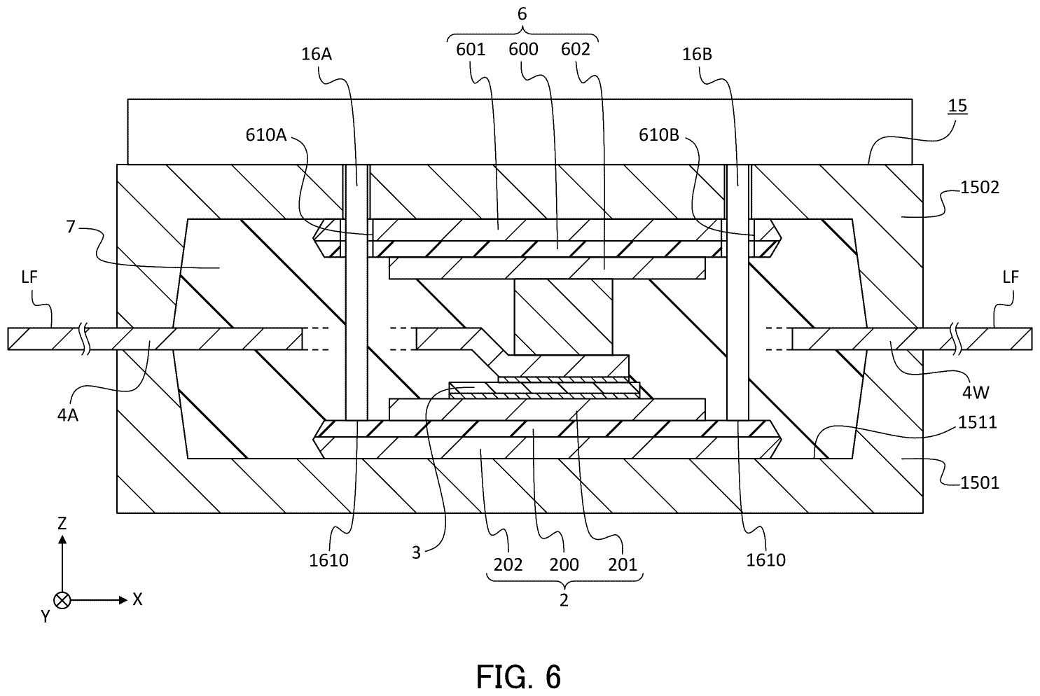

The arrangement step S2 is a step of arranging the member prepared in the preparation step S1 in the cavity of the mold and clamping the mold. The mold includes a lower mold in which a recess having a bottom surface with which the lower surface of the first heat dissipation member 2 is brought into contact is formed, and an upper mold in which a recess having a bottom surface with which the upper surface of the second heat dissipation member 6 is brought into contact is formed. As will be described later with reference to FIGS. 5 and 6, a through hole through which a pin for pressing the first heat dissipation member 2 against the bottom surface of the lower mold is inserted is formed at a position corresponding to the through hole 610 of the second heat dissipation member 6 in the upper mold.

The sealing step S3 is a step of injecting a molten insulating resin (sealing resin) as the sealing member 7 into the cavity of the clamped mold to seal the semiconductor element 3 and the like, and includes a pin pressing step S301, an injection step S302, a temporary curing step S303, a pin pulling step S304, and a main curing step S305. The pin pressing step S301 is a step of pressing the pin inserted into the through hole of the upper mold and the through hole 610 of the second heat dissipation member 6 against the first heat dissipation member 2 to press the first heat dissipation member 2 against the bottom surface of the lower mold to bring the first heat dissipation member 2 into close contact with the bottom surface of the lower mold. The injection step S302 is a step of injecting a sealing resin into the cavity of the mold in a state where the first heat dissipation member 2 is pressed against the bottom surface of the lower mold by the pin. The sealing resin to be injected may be, for example, an uncured thermosetting resin such as an uncured epoxy resin to which the inorganic filler and other additives described above are added.

The temporary curing step S303 is a step of slightly advancing the curing reaction of the uncured sealing resin injected into the cavity of the mold. In the temporary curing step S303, for example, the curing reaction is advanced to such a curing rate (sometimes referred to as curing degree or reaction rate) that the close contact between the lower surface of the first heat dissipation member 2 and the bottom surface of the lower mold by the sealing resin is secured to such an extent that the sealing resin does not enter between the first heat dissipation member 2 and the lower mold when the pin is separated from the first heat dissipation member 2 in the next pin pulling step S304, and the space (void) generated in the cavity when the pin is extracted can be filled with the scaling resin. When an epoxy-based resin is used as the sealing resin, the curing conditions (temperature and time) in the temporary curing step S303 can be, for example, 180° C. for about 90 seconds.

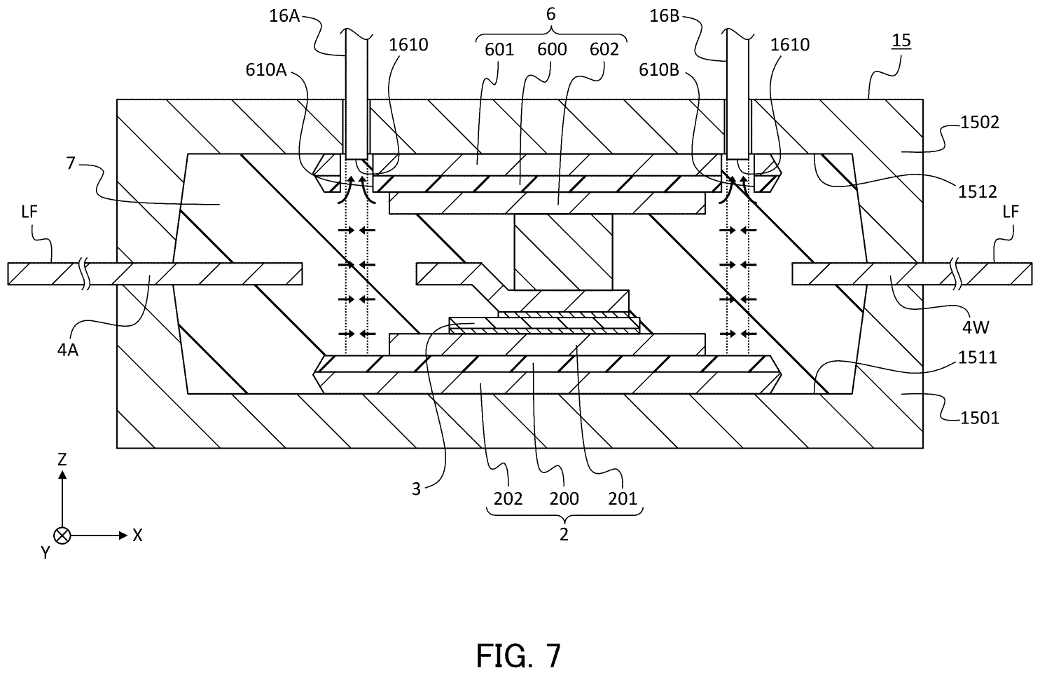

The pin pulling step S304 is a step of extracting a pin that presses the first heat dissipation member 2 against the lower mold. In the pin pulling step S304, for example, the pin is pulled out so that the tip portion of the pin is held in a state of protruding into the cavity by a predetermined protruding amount from the bottom surface of the upper mold in contact with the second heat dissipation member 6 (see FIGS. 7 and 9). The protruding amount of the pin may be, for example, about 20 μm to 100 μm, more preferably about 20 μm to 50 μm.

The main curing step S305 is a step of curing the temporarily cured sealing resin filling the cavity of the mold after the pin is pulled out to a predetermined position. When an epoxy-based resin is used as the sealing resin, the curing conditions in the main curing step S305 can be, for example, 180° C. for about 2 hours.

When the sealing resin filling the cavity of the mold is cured in the main curing step S305, the sealing step S3 is completed, and the extraction step S4 is subsequently performed. In the extraction step S4, for example, cooling of the mold and the sealing resin, releasing, trimming of the lead frame, bending of the lead 4, and the like are performed.

FIG. 5 is a cross-sectional view illustrating a state of a mold at the start of a sealing step. FIG. 6 is a cross-sectional view illustrating a state of a mold during an injection step and a temporary curing step. FIG. 7 is a cross-sectional view illustrating a state of a mold after a pin extraction step. FIGS. 5 to 7 illustrate a virtual cross-sectional configuration example similar to the cross-sectional view of FIG. 2.

At the start of the sealing step S3, the lead 4 is a part of the lead frame LF, and the outer lead is not bent as illustrated in FIG. 5. The mold 15 includes a lower mold 1501 and an upper mold 1502, and by clamping these molds, a cavity (space) 1510 corresponding to the outer shape of the sealing member 7 is formed. The lower mold 1501 is formed with a recess forming a portion of the sealing member 7 below the lead frame LF, and a bottom surface 1511 of the recess comes into contact with the lower surface of the second conductor pattern 202 of the first heat dissipation member 2 when the mold is clamped. The upper mold 1502 is formed with a recess forming a portion of the sealing member 7 above the lead frame LF, and a bottom surface 1512 of the recess comes into contact with the upper surface of the first conductor pattern 601 of the second heat dissipation member 6 when the mold is clamped. Further, in the upper mold 1502, a through hole 1520 through which the pin 16 can be inserted is formed in each of the through holes 610 of the second heat dissipation member 6 with the bottom surface 1512 of the recess as one opening end. In the following description, the bottom surface 1511 of the recess of the lower mold 1501 will be referred to as a “lower bottom surface 1511”, and the bottom surface 1512 of the recess of the upper mold 1502 will be referred to as an “upper bottom surface 1512”.

When the sealing resin is injected into the cavity 1510 in the state illustrated in FIG. 5, a part of the injected sealing resin enters between the lower bottom surface 1511 of the lower mold 1501 and the lower surface of the first heat dissipation member 2, and may remain as a burr after the sealing step. The burr remaining after the sealing step may cause, for example, a connection failure between the second conductor pattern 202 of the first heat dissipation member 2 and the cooler 8. In addition, when the step of removing the burr remaining after the sealing step is added, the manufacturing cost of the semiconductor module increases.

Therefore, in the method for manufacturing the semiconductor module 1 according to the present embodiment, as illustrated in FIG. 6, in a state where the second conductor pattern 202 of the first heat dissipation member 2 is pressed against the lower bottom surface 1511 of the lower mold 1501 by the pin 16 inserted into the through hole 1520 of the upper mold 1502 and the through hole 610 of the second heat dissipation member 6 and advanced into the cavity 1510 of the mold 15, the sealing resin 7′ is injected into the cavity 1510. At this time, the pin 16 is brought into contact with a position of the upper surface of the insulating substrate 200 of the first heat dissipation member 2, the position being a corner in a plan view of the upper surface of the insulating substrate 200. In this way, the end portion of the lower surface of second conductor pattern 202 is less likely to be separated from the lower bottom surface 1511 of the lower mold 1501. Therefore, it is possible to prevent a part of the sealing resin 7′ injected into the cavity 1510 of the mold 15 from entering between the lower bottom surface 1511 of the lower mold 1501 and the lower surface of the second conductor pattern 202 of the first heat dissipation member 2 (That is, burrs are generated after the sealing step.).

In addition, in the method for manufacturing the semiconductor module 1 according to the present embodiment, since the pin is inserted into the through hole 610 formed in the second heat dissipation member 6, the exposed area of the second heat dissipation member 6 (the upper surface of the first conductor pattern 601) on the upper surface 712 of the sealing member 7 can be easily increased. Therefore, as compared with the semiconductor device of JP 2022-67815 A, the difference between the heat dissipation performance from the lower surface 711 and the heat dissipation performance from the upper surface 712 of the sealing member 7 is reduced, and the heat generated during the operation of the semiconductor element 3 can be more effectively dissipated.

Further, in the method for manufacturing the semiconductor module 1 according to the present embodiment, after the curing reaction of the injected sealing resin 7′ is slightly advanced, as illustrated in FIG. 7, the pin 16 that has pressed the first heat dissipation member 2 against the lower bottom surface 1511 of the lower mold 1501 is pulled out. Since the curing reaction of the sealing resin 7′ in the cavity has proceeded somewhat, it is possible to suppress the sealing resin 7′ from entering between the lower surface of the first heat dissipation member 2 and the lower bottom surface 1511 of the lower mold 1501 when the pin 16 is pulled out. In addition, since the pin 16 is pulled out before the sealing resin 7′ in the cavity is completely cured, a space (gap) generated when the pin 16 is pulled out is filled with the scaling resin 7′ as illustrated in FIG. 7. Therefore, a step of injecting an additional insulating resin (sealing resin) into a space generated when the pin 16 is pulled out can be omitted, and an increase in manufacturing cost can be suppressed.

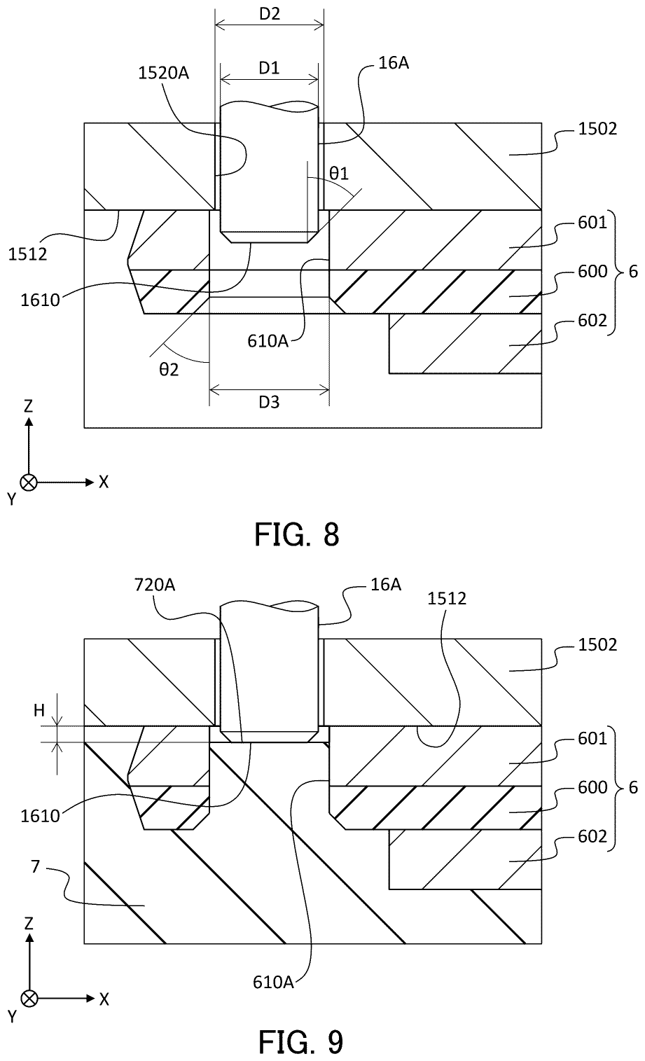

FIG. 8 is a partial cross-sectional view illustrating an example of a tip shape of a pin and a shape of a through hole of a second heat dissipation member. FIG. 9 is a partial cross-sectional view illustrating an example of a recess formed in a through hole of the second heat dissipation member in a main curing step. In FIGS. 8 and 9, a portion of the through hole 610A among the four through holes 610A to 610D of the second heat dissipation member 6 illustrated in FIG. 1 is enlarged. The other portions of the through holes 610B to 610D may be similar to the portion of the through hole 610A illustrated in FIGS. 8 and 9.

When the tip portion of the pin 16 (the portion in contact with the first heat dissipation member 2) is a flat surface 1610 substantially parallel to the upper surface of the insulating substrate 200 of the first heat dissipation member 2 as illustrated in FIGS. 5 to 7, a pressing load is dispersed in the contact surface when the pin is pressed against the upper surface of the insulating substrate 200 of the first heat dissipation member 2, so that the pin is less likely to be scratched. The tip portion of the pin 16 may taper toward the flat surface 1610 as illustrated in FIG. 8. When the tip portion of the pin 16 is tapered, the pin 16 is easily inserted into the through hole 610 of the second heat dissipation member 6. For example, when misalignment occurs between the through hole 1520 of the upper mold 1502 and the through hole 610 of the second heat dissipation member 6 in the arrangement step S2, the inclined surface of the tip portion of the pin 16 comes into contact with the open end of the through hole 610 of the second heat dissipation member 6 in the next pin pressing step S301, whereby the pin 16 is guided into the through hole 610 of the second heat dissipation member 6.

In addition, when the tip portion of the pin 16 is tapered, burrs are less likely to occur at the corner where the flat surface 1610 and the inclined surface are connected and the corner portion where the inclined surface and the side surface are connected, as compared with the corner where the flat surface 1610 and the side surface are connected in the pin 16 having a cylindrical shape. Therefore, in the pin pressing step S301 and the pin pulling step S304, it is possible to prevent the wall surface of the through hole 610 of the second heat dissipation member 6 and the wall surface of the through hole 1520 of the upper mold 1502 from being scratched by the burr at the tip portion of the pin 16. The angle θ1 of the inclined surface is not limited to a specific angle, but is preferably within a range of 30 degrees to 60 degrees, for example. In addition, the tip portion of the pin 16 may have a shape in which the outer periphery of the flat surface 1610 is chamfered instead of being tapered.

The relationship between the diameter D1 of the pin 16, the diameter D2 of the through hole 1520 of the upper mold 1502, and the diameter D3 of the through hole 610 of the second heat dissipation member 6 illustrated in FIG. 8 is D1<D2<D3. The diameter D1 of the pin 16 is, for example, 0.6 mm to 2 mm. The difference between the diameter D2 of the through hole 1520 of the upper mold 1502 and the diameter D1 of the pin 16 is preferably reduced within a range not hindering the vertical movement of the pin 16 so that the sealing resin 7′ does not flow between the pin 16 and the through hole 1520 of the upper mold 1502. On the other hand, the diameter D3 of the through hole 610 of the second heat dissipation member 6 is preferably larger than the diameter D1 of the pin 16 by about 0.2 mm to 1 mm, for example, in order to facilitate insertion of the pin 16. The relationship among the diameter D1 of the pin 16, the diameter D2 of the through hole 1520 of the upper mold 1502, and the diameter D3 of the through hole 610 of the second heat dissipation member 6 is not limited to the relationship D1<D2<D3. For example, D2=D3, D2≈D3, and D2>D3 may be satisfied.

In addition, as illustrated in FIG. 8, the opening end of the through hole 610 of the second heat dissipation member 6 on the lower surface side of the insulating substrate 600 may be tapered such that the opening diameter is tapered toward the upper surface. By tapering, the sealing resin 7′ easily enters the through hole 610 of the second heat dissipation member 6 when the pin 16 is pulled out in the pin pulling step S304, and generation of voids due to inflow failure of the sealing resin 7′ into the through hole 610 can be prevented. In addition, by tapering, stress at the interface between the second heat dissipation member 6 (insulating substrate 600) and the sealing member 7 at the lower end portion of the through hole 610 can be relaxed (reduced). The angle θ2 of the inclined surface when the through hole 610 of the second heat dissipation member 6 is tapered is not limited to a specific angle, but is preferably in the range of 30 degrees to 60 degrees, for example. In addition, the opening end on the lower surface side of the through hole 610 of the second heat dissipation member 6 may have a shape in which the opening end is chamfered instead of being tapered.

The through hole 610 is not limited to the portion where only the first conductor pattern 601 and the insulating substrate 600 illustrated in FIG. 8 are stacked, and may be provided at the portion where the first conductor pattern 601, the insulating substrate 600, and the second conductor pattern 602 are stacked. Further, the inner wall surface of the through hole 610, particularly the inner wall surface of the through hole of the first conductor pattern 601 may be roughened. For the roughening, etching, shot peening, or the like is used, and in particular, in a range of 0.1 μm to 5 μm in surface roughness Ra (center line average roughness), the adhesion between the inner wall surface of the through hole of the first conductor pattern 601 and the sealing member 7 is improved, and the intrusion of moisture and a corrosive gas from the outside can be reduced. The surface roughness can be measured with a stylus type roughness meter or an optical roughness meter.

Further, when the pin 16 is pulled out to a position where the flat surface 1610 of the pin 16 retreats from the upper bottom surface 1512 of the upper mold 1502 in the pin pulling step S304, a part of the sealing resin 7′ flows into the through hole 1520 of the upper mold 1502, and a portion protruding from the upper surface of the second heat dissipation member 6 is generated in the scaling member 7. In this case, for example, a step of removing a portion protruding from the upper surface of the second heat dissipation member 6 is added, and the manufacturing cost of the semiconductor module increases. Therefore, as described above with reference to FIG. 7, the main curing step S305 is preferably performed in a state in which the flat surface 1610 of the pin 16 protrudes toward the inside of the cavity from the upper bottom surface 1512 of the upper mold 1502. The protruding amount (that is, the distance from the upper bottom surface 1512 of the upper mold 1502 to the flat surface 1610 of the pin 16) H of the pin 16 illustrated in FIG. 9 is not limited to a specific protruding amount, but if the protruding amount H of the pin 16 is too large, there is a possibility that foreign matter is mixed into the recess 720 generated in the through hole 610 of the second heat dissipation member 6, or the semiconductor module 1 is damaged due to another member being caught during handling. In addition, moisture, a corrosive gas, or the like may enter from the outside through the through hole, particularly through the interface between the first conductor pattern 601 and the sealing member 7. Therefore, the protruding amount H of the pin 16 (the amount of recess from the outer surface of the module) is preferably in the range of 20 μm to 100 μm, and more preferably in the range of 20 μm to 50 μm, for example. In particular, the thickness is preferably less than 50% of the thickness of the first conductor pattern 601 from the viewpoint of corrosion resistance. When the tip portion of the pin 16 is tapered, the recess 720 may have a shape having a taper corresponding to the shape of the tip portion of the pin 16. The shape and protruding amount H of the through hole 610 are the same in the through hole 210 of the first heat dissipation member 2 in a second embodiment described later.

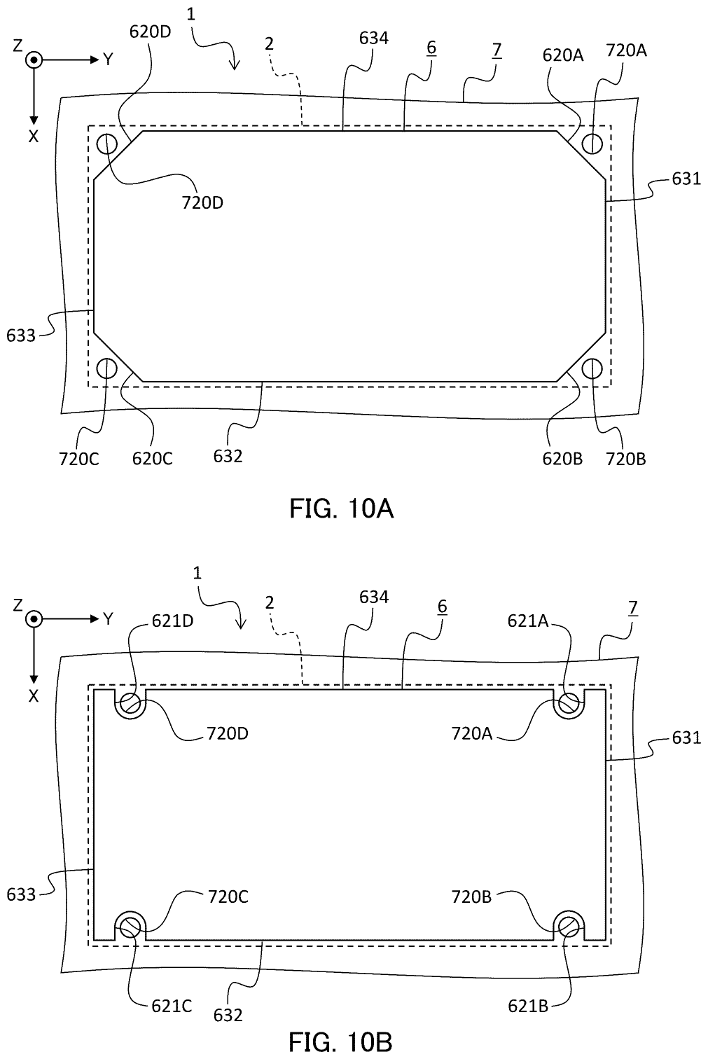

FIGS. 10A and 10B are plan views illustrating a modification of the planar shape of the second heat dissipation member. FIGS. 10A and 10B illustrate only a portion of the semiconductor module 1 illustrated in FIG. 1 where the second heat dissipation member 6 is disposed and a region corresponding to the periphery thereof, respectively. In FIGS. 10A and 10B, the long sides 632 and 634 and the short sides 631 and 633 of the broken line representing the outer shape of the first heat dissipation member 2 and the solid line representing the outer shape of the second heat dissipation member 6 may partially or entirely overlap. A part of the solid line representing the outer shape of the second heat dissipation member 6 may pass through the outside of a region surrounded by a broken line representing the outer shape of the first heat dissipation member 2.

As a first modification, FIG. 10A illustrates an example in which planar shapes of the insulating substrate 600 and the first conductor pattern 601 of the second heat dissipation member 6 are octagonal shapes in which corners of a rectangle are obliquely cut off. Such a planar shape may be referred to as a shape in which a tapered notch 620 (620A to 620D) is provided at a corner of a rectangle represented by a straight line overlapping the long sides 632 and 634 and a straight line overlapping the short sides 631 and 322. When the second heat dissipation member 6 has such a planar shape, the pin 16 can be pressed against a portion closer to the corner of the first heat dissipation member 2 in a state where the area of the region overlapping the second heat dissipation member 6 in the first heat dissipation member 2 in the plan view of the upper surface 712 of the scaling member 7 is kept wide. In FIG. 10A, the position of the pin 16 pressed against the first heat dissipation member 2 is represented by the position of the recess 720 formed on the upper surface 712 of the sealing member 7.

The shape of the notch 620 included in the corner portion of the rectangle in the planar shape of the second heat dissipation member 6 in a plan view is not limited to the shape illustrated in FIG. 10A in which the corner is represented by a side in an oblique direction with respect to each of the long sides 632 and 634 and the short sides 631 and 633. The planar shape of the notch 620 to be included in the corner may be, for example, a shape represented by a combination of a side parallel to the long sides 632 and 634 and a side in a direction parallel to the short sides 631 and 633, or may be a shape including an arc.

FIG. 10B illustrates, as a second modification, an example in which planar shapes of the insulating substrate 600 and the first conductor pattern 601 of the second heat dissipation member 6 are shapes in which notches 621 are provided in the long sides 632 and 634 of the rectangle. When the second heat dissipation member 6 has such a planar shape, the pin 16 can be pressed against a portion closer to the end side (end sides corresponding to long sides 632 and 634 of the second heat dissipation member 6) of the first heat dissipation member 2 in a state where the area of the region overlapping the second heat dissipation member 6 in the first heat dissipation member 2 in the plan view of the upper surface 712 of the sealing member 7 is kept wide. In FIG. 10B, the position of the pin 16 pressed against the first heat dissipation member 2 is represented by the position of the recess 720 formed on the upper surface 712 of the sealing member 7.

The shape of the notch 621 included in each of the long sides 632 and 634 of a rectangle in the planar shape of the second heat dissipation member 6 in a plan view is not limited to the U-shape illustrated in FIG. 10B. The planar shape of the notch 621 may be, for example, a shape represented by a combination of a side parallel to the long sides 632 and 634 and a side in a direction parallel to the short sides 631 and 633, or may be an arc or a shape including an arc different from the U-shape. In addition, the pin 16 may be pressed against a portion of the first heat dissipation member 2 close to the end sides corresponding to the short sides 631 and 633 of the second heat dissipation member 6, and in this case, the notch 621 is included in the short sides 631 and 633 of the rectangle.

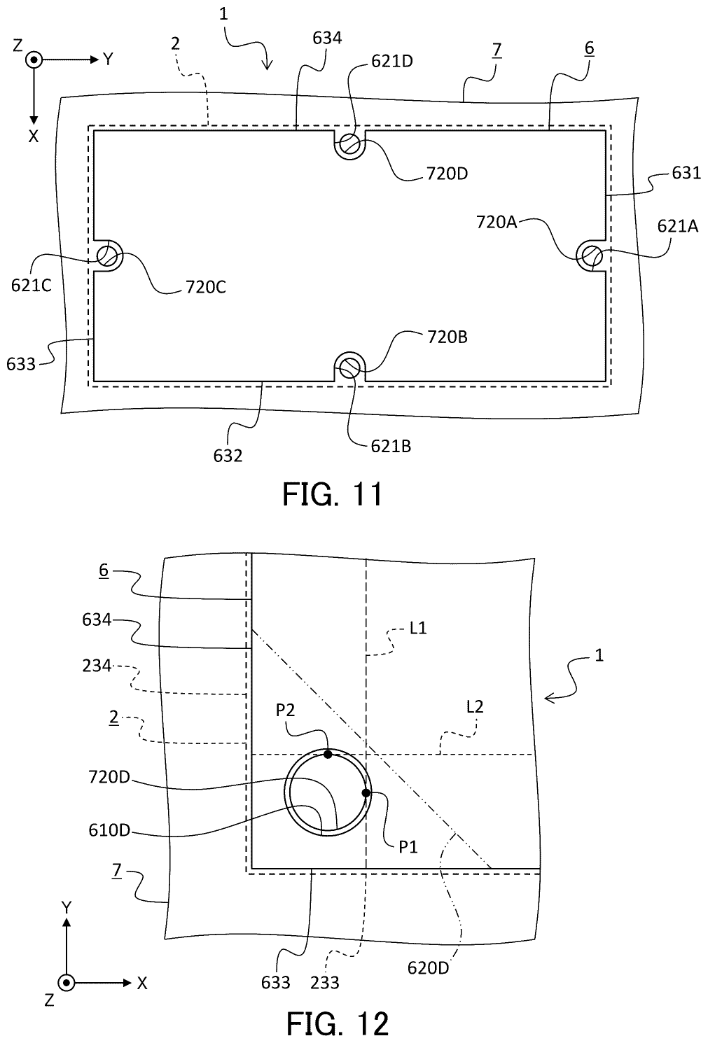

FIG. 11 is a plan view illustrating a modification of the arrangement of pins to be pressed against the first heat dissipation member. FIG. 11 illustrates only a portion of the semiconductor module 1 illustrated in FIG. 1 where the second heat dissipation member 6 is disposed and a region corresponding to the periphery thereof. In FIG. 11, the long sides 632 and 634 and the short sides 631 and 633 of the broken line representing the outer shape of the first heat dissipation member 2 and the solid line representing the outer shape of the second heat dissipation member 6 may partially or entirely overlap. A part of the solid line representing the outer shape of the second heat dissipation member 6 may pass through the outside of a region surrounded by a broken line representing the outer shape of the first heat dissipation member 2. In FIG. 11, the arrangement of the pins 16 is represented by the arrangement of the recesses 720 formed in the upper surface 712 of the sealing member 7.

As illustrated in FIG. 11, the pin 16 used in the sealing step S3 described above may be disposed so as to be pressed against the center position in the extending direction of the side of the portion along each of the sides 631 to 634 of the first heat dissipation member 2 in the plan view of the upper surface 712 of the sealing member 7. In this example, the planar shape of the second heat dissipation member 6 is not limited to the shape in which the U-shaped notch 621 is included in each of the sides 631 to 634 as illustrated in FIG. 11. The shape of the notch 621 included in each side may be a shape different from the U-shape. Further, the planar shape of the second heat dissipation member 6 may be a shape having the through hole 610 through which the pin 16 is inserted as illustrated in FIG. 1. Furthermore, the arrangement of the pins 16 is not limited to the above-described arrangement, and for example, the pins may be arranged at any number of positions in a region not overlapping the leads 4 (inner leads) in the sealing member 7 in a region along the outer periphery of the first heat dissipation member 2 in a plan view.

The planar shape of the second heat dissipation member 6 that can be adopted in the semiconductor module 1 according to the present embodiment is not limited to the above-described shape. The planar shape of the second heat dissipation member 6 can be appropriately changed according to the position of the pin 16 pressed against the first heat dissipation member 2. The planar shape of the second heat dissipation member 6 can be a shape in which a part of the second heat dissipation member 6 is included closer to the end side of the first heat dissipation member than a position represented by a line passing through a point farthest from the end side of the first heat dissipation member 2 and extending in a direction parallel to the end side among the recesses 720 that can indicate the positions of the pins 16 in the plan view of the upper surface 712 of the scaling member 7.

FIG. 12 is a view illustrating a feature of a planar shape of the second heat dissipation member that can be adopted in the semiconductor module according to the first embodiment. FIG. 12 illustrates only a portion of the second heat dissipation member 6 in the semiconductor module 1 illustrated in FIG. 1 where the through hole 610D is formed and a region corresponding to the periphery of the portion. The other portions of the through holes 610A to 610C may be similar to the portion of the through hole 610D illustrated in FIG. 12.

In the semiconductor module 1 illustrated in FIG. 12, the recess 720D in the scaling member 7 indicating the position of the pin 16 used in the sealing step S3 is in the through hole 610D of the second heat dissipation member 6. In FIG. 12, a circle representing the recess 720D may overlap (coincide with) a circle representing the through hole 610D. In the recess 720D, a line L1 passing through a point PI farthest from the long side 234 of the first heat dissipation member 2 and parallel to the long side 234 and a line L2 passing through a point P2 farthest from the short side 233 and parallel to the short side 233 both pass through the second heat dissipation member 6. In addition, as in the second heat dissipation member 6 illustrated in FIG. 10A, also in a case where the tapered notch 620D indicated by a two-dot chain line in FIG. 12 is formed, the line L1 and the line L2 pass through the second heat dissipation member 6. Although detailed description is omitted, also in the case of the planar shape of the second heat dissipation member 6 described above with reference to FIGS. 10B and 11, in the recess 720D, both the line L1 passing through the point P1 farthest from the long side 234 and parallel to the long side and the line L2 passing through the point P2 farthest from the short side 233 and parallel to the short side 233 of the first heat dissipation member 2 pass through the second heat dissipation member 6.

In the semiconductor device of JP 2022-67815 A, for example, since the long side of the heat dissipation member corresponding to the second heat dissipation member 6 passes through the side opposite to the long side 234 of the first heat dissipation member 2 with the line L1 illustrated in FIG. 12 as a boundary, there is a difference in the exposed area between the two heat dissipation members. On the other hand, in the semiconductor module 1 of the present embodiment having the features described above with reference to FIG. 12, the exposed area of the second heat dissipation member 6 on the upper surface 712 of the sealing member 7 can be widened to the same extent as the exposed area of the first heat dissipation member 2 on the lower surface 711. Therefore, as compared with the semiconductor device of JP 2022-67815 A, the difference between the heat dissipation performance from the lower surface 711 and the heat dissipation performance from the upper surface 712 of the sealing member 7 is reduced, and the heat generated during the operation of the semiconductor element 3 can be more effectively dissipated.

Note that the pin 16 used in the sealing step S3 of the semiconductor module according to the present embodiment is not limited to a columnar shape, and may be a polygonal columnar shape.

In addition, the first heat dissipation member 2 and the second heat dissipation member 6 in the semiconductor module 1 according to the present embodiment are not limited to those having the above-described configurations. For example, the insulating substrate 200 of the first heat dissipation member 2 and the insulating substrate 600 of the second heat dissipation member 6 are not limited to resin insulating sheets, and may be ceramic substrates. The ceramic substrate may be a substrate made of, for example, a ceramic material such as aluminum oxide (Al₂O₃), aluminum nitride (AlN), silicon nitride (Si₃N₄), or a composite material of aluminum oxide (Al₂O₃) and zirconium oxide (ZrO₂). A heat dissipation member using a ceramic substrate as an insulating substrate may be referred to as a direct copper bonding (DCB) substrate or an active metal brazing (AMB) substrate. The insulating substrate 200 of the first heat dissipation member 2 and the insulating substrate 600 of the second heat dissipation member 6 may be a substrate in which a base material such as glass fiber is impregnated with an insulating resin, a substrate in which a surface of a flat plate-shaped metal core is coated with an insulating resin, or the like. Further, the combination of the materials of the insulating substrate 600, the first conductor pattern 601, and the second conductor pattern 602 of the second heat dissipation member 6 may be the same as or different from the combination of the materials of the insulating substrate 200, the first conductor pattern 201, and the second conductor pattern 202 of the first heat dissipation member 2. In the first heat dissipation member 2, for example, the second conductor pattern 202 may be omitted. In the second heat dissipation member 6, for example, the second conductor pattern 602 may be omitted.

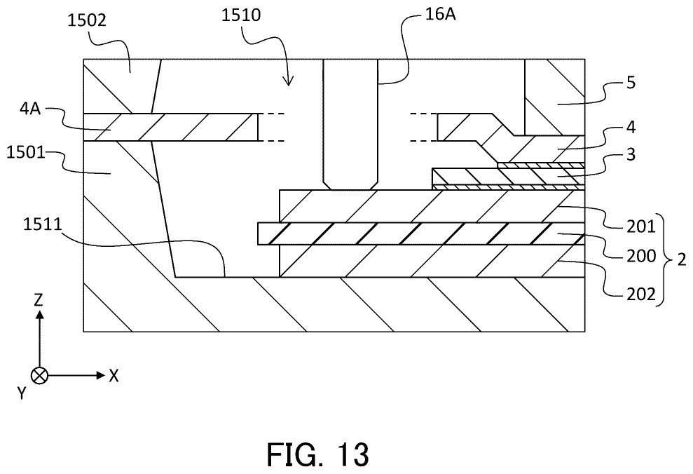

FIG. 13 is a partial cross-sectional view illustrating a modification of the method of pressing the heat dissipation member against the mold.

The pin 16 illustrated in FIG. 6 is in contact with the upper surface of the insulating substrate 200 of the first heat dissipation member 2. However, in the first heat dissipation member 2, the first conductor pattern 201 or another conductor pattern may be disposed at a position on the upper surface of the insulating substrate 200 where the pin 16 is in contact. That is, in pin pressing step S301, as illustrated in FIG. 13, pin 16 may be pressed against the first conductor pattern 201 disposed on the upper surface of the insulating substrate 200 of the first heat dissipation member 2. In particular, when the insulating substrate 200 is a ceramic substrate, the ceramic substrate may be broken by pressing the pins 16 against the ceramic substrate, and thus it is preferable to press the pins 16 against the conductor pattern arranged on the upper surface of the insulating substrate 200. The conductor pattern different from the first conductor pattern 201 against which the pin 16 is pressed may be a part of the conductor pattern used as the wiring of the circuit, or may be formed separately from the conductor pattern used as the wiring of the circuit.

In addition, the first heat dissipation member 2 illustrated in FIG. 6 and the like may include the insulating substrate 200 in which an insulating resin is formed in a sheet shape, and is manufactured by a known method for manufacturing a printed wiring board. This type of the first heat dissipation member 2 is divided by a method of forming V-shaped grooves on the front surface and the back surface of the member and dividing the V-shaped grooves, which may be referred to as a V-cut method, in a manufacturing step. In the first heat dissipation member 2 to which the V-cut method is applied, as illustrated in FIG. 6 and the like, the angle formed by the end portion (side surface) in the in-plane direction of the upper surface of the insulating substrate 200 and the lower bottom surface 1511 of the lower mold 1501 is an acute angle. When such a first heat dissipation member 2 is used, for example, as compared with the case where the angle formed by the side surface of the second conductor pattern 202 and the lower bottom surface 1511 of the lower mold 1501 illustrated in FIG. 13 is 90 degrees, the sealing resin 7′ injected into the cavity 1510 is less likely to enter between the lower surface of the second conductor pattern 202 and the lower bottom surface 1511 of the lower mold 1501. In addition, in the semiconductor module 1 obtained through the sealing step S3, when the angle formed by the side surface of the second conductor pattern 202 and the lower surface 711 of the sealing member 7 is an acute angle, a portion of the scaling member 7 along the side surface of the second conductor pattern 202 serves as a wedge, and the first heat dissipation member 2 is less likely to fall off from the sealing member 7.

### Second Embodiment

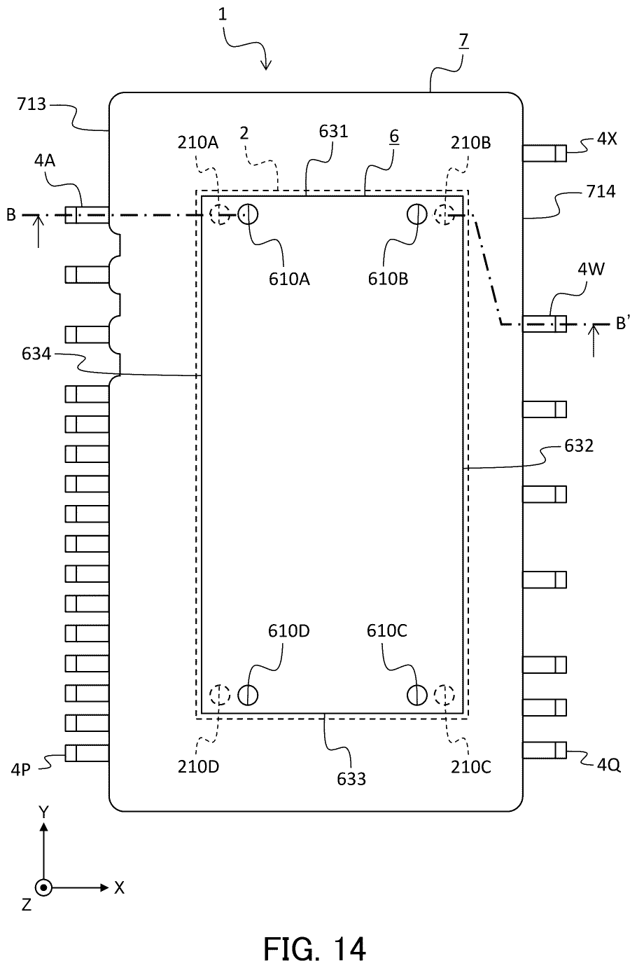

FIG. 14 is a plan view of a semiconductor module according to the second embodiment. FIG. 15 is a cross-sectional view illustrating a configuration example in a sealing member in the semiconductor module illustrated in FIG. 14. The cross-sectional view of FIG. 15 illustrates a cross-sectional configuration example of a semiconductor module 1 cut by a virtual line B-B′ obtained by connecting an alternate long and short dash line passing through one lead 4A located on the negative side in the X direction to another alternate long and short dash line passing through another lead 4W located on the positive side in the X direction in the semiconductor module 1 illustrated in FIG. 14. In FIG. 14, a broken line representing the outer shape of a first heat dissipation member 2 and a solid line representing the outer shape of a second heat dissipation member 6 may partially or entirely overlap each other. A part or all of the solid line representing the outer shape of the second heat dissipation member 6 may pass through the outside of a region surrounded by a broken line representing the outer shape of the first heat dissipation member 2. In FIGS. 14 and 15, some reference numerals for the same components as those of the semiconductor module 1 illustrated in FIGS. 1 and 2 are omitted.

Similarly to the semiconductor module 1 according to the first embodiment, the semiconductor module 1 according to the present embodiment includes a first heat dissipation member 2, a semiconductor element 3, leads 4 (4A to 4X), a spacer 5, a second heat dissipation member 6, and a sealing member 7. The semiconductor module 1 according to the present embodiment is different from the semiconductor module 1 according to the first embodiment in that a through hole 210 (210A to 210D) penetrating the insulating substrate 200 and the second conductor pattern 202 is formed at an end portion of the first heat dissipation member 2 in a plan view of the upper surface 712 of the sealing member 7 and at a position not overlapping a through hole 610 (610A to 610D) of the second heat dissipation member 6. Similarly to the sealing member 7 in the through hole 610 of the second heat dissipation member 6, the through hole 210 of the first heat dissipation member 2 is filled with the sealing member 7 so as to form a recess 740 (740A, 740B, and the like in FIG. 15) retracted in the direction from the lower surface to the upper surface of the second conductor pattern 202.

The manufacturing process of the semiconductor module 1 according to the present embodiment includes the preparation step S1, the arrangement step S2, the sealing step S3, and the extraction step S4 described above with reference to FIG. 4. The sealing step S3 includes a pin pressing step S301, an injection step S302, a temporary curing step S303, a pin pulling step S304, and a main curing step S305. The semiconductor module 1 according to the present embodiment is manufactured by the procedure described in the first embodiment. However, the configuration of the mold 15 used in the sealing step S3 is different from the configuration described in the first embodiment.

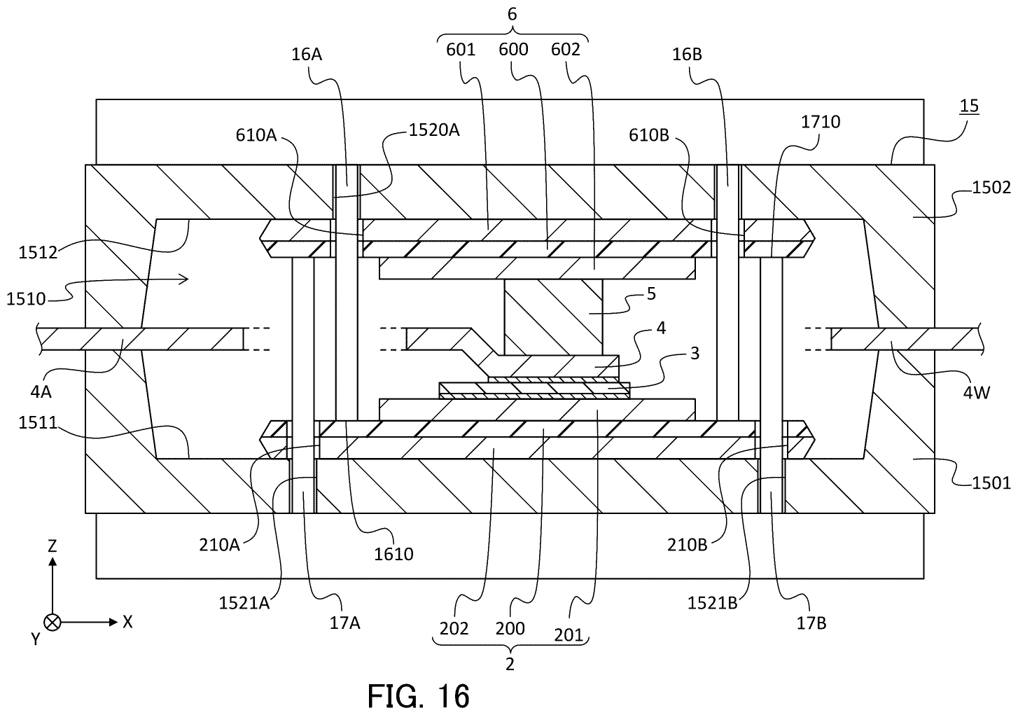

FIG. 16 is a cross-sectional view illustrating a configuration example of a mold used for manufacturing the semiconductor module according to the second embodiment. FIGS. 16 illustrates a virtual cross-sectional configuration example similar to the cross-sectional view of FIG. 15. In FIG. 16, some reference numerals for the same components as those of the mold 15 illustrated in FIGS. 5 and 6 are omitted.

The configuration of the upper mold 1502 in the mold 15 used in the sealing step S3 for manufacturing the semiconductor module 1 according to the present embodiment is as described in the first embodiment, and the through hole 1520 through which the pin 16 for pressing the first heat dissipation member 2 against the lower bottom surface 1511 of the lower mold 1501 is inserted is formed. The lower mold 1501 of the mold 15 according to the present embodiment has the through hole 1521 through which the pin 17 for pressing the second heat dissipation member 6 against the upper bottom surface 1512 of the upper mold 1502 is inserted. That is, the injection step S302 in the sealing step S3 according to the present embodiment is performed in a state where first pin 16 presses the first heat dissipation member 2 against the lower bottom surface 1511 of the lower mold 1501, and the second pin 17 presses the second heat dissipation member 6 against the upper bottom surface 1512 of the upper mold 1502. Thereafter, the temporary curing step S303, the pin pulling step S304, and the main curing step S305 are performed according to the procedure described in the first embodiment. In the pin pulling step S304, the first pin 16 that has pressed the first heat dissipation member 2 against the lower bottom surface 1511 of the lower mold 1501 and the second pin 17 that has pressed the second heat dissipation member 6 against the upper bottom surface 1512 of the upper mold 1502 are pulled out to positions where they protrude into the cavity by the protruding amount H (see FIG. 9).

In the semiconductor module 1 of the present embodiment, the planar shape of the first heat dissipation member 2 and the planar shape of the second heat dissipation member 6 in a plan view of the upper surface 712 of the sealing member 7 can be formed into shapes having the features described above with reference to FIG. 12. Therefore, on both surfaces of the lower surface 711 of the sealing member 7 from which the first heat dissipation member 2 is exposed and the upper surface 712 of the sealing member 7 from which the second heat dissipation member 6 is exposed, it is possible to prevent generation of burrs due to flow of the sealing resin 7′ between the heat dissipation member and the bottom surface of the mold 15 with which the heat dissipation member is brought into contact.

In the semiconductor module 1 according to the present embodiment, the planar shape of the second heat dissipation member 6 in a plan view of the upper surface 712 of the sealing member 7 can be selected from various shapes including the shape exemplified in the first embodiment and having the features described above with reference to FIG. 12. The arrangement of the pins 16 and 17 in the mold 15 used for manufacturing the semiconductor module 1 according to the present embodiment can be selected from various arrangements including the arrangement exemplified in the first embodiment. The arrangement of the first pin 16 and the arrangement of the second pin 17 are not limited to the arrangements represented by the through holes 610 and 210 illustrated in FIG. 14. For example, the arrangement of the first pin 16 and the second pin 17 at one corner may be an arrangement in which these two pins are aligned along the long side of the second heat dissipation member 6. Further, for example, the first pin 16 may be disposed to be pressed against a corner of the first heat dissipation member 2, and the second pin 17 may be disposed to be pressed against a center position in an extending direction of a side of each side of the second heat dissipation member 6, or vice versa. Although not described in detail, other technical features described in the first embodiment may be applied to the semiconductor module 1 according to the present embodiment.

The semiconductor module 1 of the above-described embodiment can be applied to, for example, an industrial power conversion device such as an inverter device that drives a motor of an elevator, an escalator, an air conditioning system of a building, or the like. Note that the application of the semiconductor module 1 is not limited to a specific application. For example, the semiconductor module 1 can also be applied to a power conversion device such as an inverter device that drives a motor of a vehicle such as a four-wheeled automobile, a two-wheeled vehicle, or a railway vehicle.

The switching element in the semiconductor element 3 in the semiconductor module 1 applied to the power conversion device may include a power metal oxide semiconductor field effect transistor (MOSFET), a bipolar junction transistor (BJT), or the like. When the switching element is a MOSFET element, the main electrode on a lower surface side of the semiconductor element 3 may be referred to as a drain electrode, and the main electrode on the upper surface side may be referred to as a source electrode. Furthermore, the diode element of the semiconductor element 3 may include, for example, a schottky barrier diode (SBD), a junction barrier schottky (JBS) diode, a merged PN schottky (MPS) diode, a PN diode, or the like. In addition, the control electrodes provided on the upper surface of the semiconductor element 3 may include a gate electrode and an auxiliary electrode. For example, the auxiliary electrode may be an auxiliary emitter electrode or an auxiliary source electrode electrically connected to the main electrode on the upper surface side and serving as a reference potential with respect to a gate potential. Furthermore, the auxiliary electrode may be a temperature sensing electrode that is electrically connected to a temperature sensing unit that may be included in an inverter device or the like including the semiconductor module 1 and measures temperature of the semiconductor element 3.

The semiconductor element 3 of the semiconductor module 1 is not limited to one in which the IGBT element and the FWD element described above are formed on a single semiconductor substrate, and may include a semiconductor element in which an IGBT element is formed and a semiconductor element in which a diode element is formed.

As described above, the circuit formed in the semiconductor module 1 is not limited to the power conversion circuit that converts direct current into alternating current, and may be another circuit or may include another circuit.

In the method for manufacturing the semiconductor module 1 described above, the pins 16 and 17 that are inserted into the through hole 1520 of the upper mold 1502 and the through hole 1521 of the lower mold 1501 and advance into the cavity are used, but the present invention is not limited thereto, and the pins 16 and 17 may be fixed to the upper mold 1502 and the lower mold 1501, respectively. When the pins are fixed to the upper mold and the lower mold, for example, after the semiconductor element 3 is sealed using such a mold, an insulating resin (scaling) is additionally injected into a space corresponding to the shape of the pins remaining in the sealing member 7 to close the space. The recess 720 on the upper surface 712 of the sealing member 7, which is a trace of the injection of the sealing resin 7′ by pressing the pin 16 against the first heat dissipation member 2, may include a portion overlapping the first heat dissipation member 2 in the plan view of the upper surface 712 and a portion not overlapping the first heat dissipation member 2. Similarly, the recess 740 on the lower surface 711 of the sealing member 7, which is a trace of the injection of the sealing resin 7′ by pressing the pin 17 against the second heat dissipation member 6, may include a portion overlapping the second heat dissipation member 6 in the plan view of the upper surface 712 and a portion not overlapping the second heat dissipation member 6.

Hereinafter, feature points in the above-described embodiment will be summarized.

A semiconductor module according to the embodiment described above includes: a sealing member that seals a semiconductor element; a first heat dissipation member exposed from a first surface of the sealing member; and a second heat dissipation member exposed from a second surface opposite to the first surface of the sealing member, in which a recess that is located at an end portion of the first heat dissipation member in a plan view of the second surface and overlaps with the first heat dissipation member and is retracted closer to the first surface than the second surface is formed on the second surface of the sealing member, and a planar shape of the second heat dissipation member in a plan view of the second surface is a shape in which a line parallel to a side of the first heat dissipation member passing through a point farthest from the side of the first heat dissipation member close to the recess in the recesses passes through the second heat dissipation member.

In the semiconductor module according to the above embodiment, the recess is located at a corner of the first heat dissipation member in a plan view of the second surface of the scaling member.

In the semiconductor module according to the above-described embodiment, the recess is located at a center in an extending direction of a side of a portion along the side of the first heat dissipation member in a plan view of the second surface of the sealing member.

In the semiconductor module according to the above-described embodiment, the second heat dissipation member is formed with a through hole surrounding the recess in a plan view of the second surface of the sealing member.

In the semiconductor module according to the above embodiment, the planar shape of the second heat dissipation member is a shape in which a notch is included at a corner of a rectangle.

In the semiconductor module according to the above embodiment, the planar shape of the second heat dissipation member is a shape in which a notch is included in a side of a rectangle.

In the semiconductor module according to the above embodiment, on the first surface of the sealing member, there is formed a second recess that is an end portion of the second heat dissipation member in a plan view of the first surface, overlaps the second heat dissipation member at a position not overlapping the recess of the second surface of the sealing member, and is retracted toward the second surface side with respect to the first surface, and a planar shape of the first heat dissipation member in a plan view of the first surface is a shape in which a line parallel to a side of the second heat dissipation member passing through a point farthest from the side of the second heat dissipation member close to the second recess in the second recess passes through the first heat dissipation member.

In the semiconductor module according to the above embodiment, a power conversion circuit including the semiconductor element 3 is sealed in the sealing member 7.

The semiconductor module according to the above embodiment further includes a lead including an inner lead portion embedded in the sealing member and an outer lead portion extending outward from an end surface of the sealing member in a direction parallel to an in-plane direction of the second surface, in which the outer lead portion of the lead is bent at a predetermined bending position in an extending direction so that the extending direction is a direction toward the second surface.

The semiconductor module according to the above embodiment further includes a cooler connected to an exposed surface of the first heat dissipation member.

It is noted that the present invention is not limited to the above-described embodiments, and various changes, substitutions, and modifications may be made without departing from the spirit of the technical idea. Further, when the technical idea can be realized in another manner by the progress of the technology or another derived technology, the technical idea may be carried out by using a method thereof. Therefore, the claims cover all implementations that may be included within the scope of the technical idea.

As described above, the present invention can alleviate the restriction of the heat dissipation member in the double-sided heat dissipation type semiconductor module in which the heat dissipation member is exposed on the pair of surfaces facing opposite directions of the sealing member, and can improve the heat dissipation performance, and is particularly advantageous for application to a high withstand voltage power conversion device.

What is claimed is:

1. A semiconductor module comprising:
a sealing member that seals a semiconductor element;
a first heat dissipation member exposed from a first surface of the sealing member; and
a second heat dissipation member exposed from a second surface opposite to the first surface of the sealing member, wherein
a recess that is located at an end portion of the first heat dissipation member in a plan view of the second surface and overlaps with the first heat dissipation member and is retracted closer to the first surface than the second surface is formed on the second surface of the sealing member, and
a planar shape of the second heat dissipation member in a plan view of the second surface is a shape in which a line parallel to a side of the first heat dissipation member passing through a point farthest from the side of the first heat dissipation member close to the recess in the recesses passes through the second heat dissipation member.

2. The semiconductor module according to claim 1, wherein the recess is located at a corner of the first heat dissipation member in a plan view of the second surface of the sealing member.

3. The semiconductor module according to claim 1, wherein the recess is located at a center in an extending direction of a side of a portion along the side of the first heat dissipation member in a plan view of the second surface of the sealing member.

4. The semiconductor module according to claim 1, wherein the second heat dissipation member is formed with a through hole surrounding the recess in a plan view of the second surface of the sealing member.

5. The semiconductor module according to claim 1, wherein the planar shape of the second heat dissipation member is a shape in which a notch is included in a corner of a rectangle.

6. The semiconductor module according to claim 1, wherein the planar shape of the second heat dissipation member is a shape in which a notch is included in a side of a rectangle.

7. The semiconductor module according to claim 1, wherein
on the first surface of the sealing member, there is formed a second recess that is an end portion of the second heat dissipation member in a plan view of the first surface, overlaps the second heat dissipation member at a position not overlapping the recess of the second surface of the sealing member, and is retracted toward the second surface side with respect to the first surface, and
a planar shape of the first heat dissipation member in a plan view of the first surface is a shape in which a line parallel to a side of the second heat dissipation member passing through a point farthest from the side of the second heat dissipation member close to the second recess in the second recess passes through the first heat dissipation member.

8. The semiconductor module according to claim 1, wherein a power conversion circuit including the semiconductor element is sealed in the sealing member.

9. The semiconductor module according to claim 1, further comprising:
a lead including an inner lead portion embedded in the sealing member and an outer lead portion extending outward from an end surface of the sealing member in a direction parallel to an in-plane direction of the second surface, wherein
the outer lead portion of the lead is bent at a predetermined bending position in an extending direction so that the extending direction is a direction toward the second surface.

10. The semiconductor module according to claim 9, further comprising: a cooler connected to an exposed surface of the first heat dissipation member.
